(19) United States
(12) Patent Application Publication
(10) Pub. No.: US 2011/0149490 A1
(43) Pub. Date: Jun. 23, 2011

(54) CONTAINER OF DISPLAY DEVICE

(75) Inventors: Young-Moo Seo, Gyeonggi-do (KR); Hyo-Sang Park, Gyeonggi-do (KR); Eui-Su Kim, Gyeonggi-do (KR)

(73) Assignee: SUN PHARMACEUTICAL INDUSTRIES LTD, Mumbai (IN)

(21) Appl. No.: 12/935,841

(22) PCT Filed: Dec. 24, 2008
(86) PCT No.: PCT/KR2008/007652

§ 371 Date: Dec. 22, 2010

(30) Foreign Application Priority Data
Mar. 31, 2008 (KR) 10-2008-0030070

(51) Int. Cl. H05K 7/00

(52) U.S. Cl. 361/679.01

(57) ABSTRACT

Provided is a container of a display device. The container includes a lower protector on which the display device is seated and an upper protector covering the lower protector. The lower protector includes a display seat on which a lower portion of the display device is seated and openings for exposing a functional part of the display device provided in the lower portion of the display device to the outside of the lower protector in a state where the display device is seated on the display seat.

### TECHNICAL FIELD

Embodiments relate to a container of a display device.

### BACKGROUND ART

A planar display is a device through which a user can watch pictures. The planar display can be installed in a small space. Thus, in recent, the planar display is being established as a main part of a display market. The planar display has a narrow width in front and rear directions. Thus, there is a limitation that the planar display is vulnerable to overturning of the front and rear directions at a manufacturing field of the planar display or during sale and use due to the narrow width of the front and rear directions.

Typically, in order to stably treat the planar display, a protection part formed of styrofoam is attached to four corners of the planar display, and then, the planar display including the protection part is received into a box. As a result, it prevents the planar display from being damaged by an external impact even if the box falls down.

Although the planer display is stably packed using such a packing structure, but it is impossible to test the product without entirely removing the packing when the product is completely packed. Thus, it is difficult to confirm whether the product is normally operated and upgrade a program of the planar display when customers request the test or upgrade of the product at a selling spot. That is to say, it is impossible to operate the planer display without entirely dismantling a container to pull out the planer display.

### DISCLOSURE OF INVENTION

### Technical Problem

Embodiments provide a container of a display device in which an operation condition thereof can be checked, and a post-operation can be performed without entirely dismantling the container of the display device.

### Technical Solution

In one embodiment, a container of a display device includes: a lower protector on which the display device is seated; and an upper protector covering the lower protector, wherein the lower protector includes: a display seat on which a lower portion of the display device is seated; and openings for exposing a functional part of the display device provided in the lower portion of the display device to the outside of the lower protector in a state where the display device is seated on the display seat.

In another embodiment, a container of a display device includes: a lower protector on which the display device is seated; and an upper protector covering the lower protector, wherein the lower protector includes: left and right display seats for supporting at least both end portions of the display device; a connection member connecting the left display seat to the right display seat; and openings defined between the left and right display seats to expose a functional part of the display device provided in a lower portion of the display device to the outside of the lower protector in a state where the display device is seated on the display seat.

In further another embodiment, a container of a display device includes: a lower protector on which the display device is seated; and an upper protector covering the lower protector, wherein the lower protector includes: left and right display seats for supporting at least lower portion of the display device, the left and right display seats being provided as separate parts; openings defined between the left and right display seats to expose at least one of a remote control receiving part, a control part, a power code terminal, a label part and a signal terminal of the display device to the outside; and a bottom member for supporting each of the seats.

### ADVANTAGEOUS EFFECTS

According to the proposed embodiments, customers can conveniently check the operation condition of a desired product before they begin purchasing the product, and also, producers can easily perform additional operations such as a software upgrade without entirely removing the packing.

Also, since the container can be used as an upending device of the display device, operations that correspond to those to be requested at selling, producing, and post-operating spots can be easily performed.

### BRIEF DESCRIPTION OF DRAWINGS

FIGS. 1 and 2 are a perspective view and an exploded perspective view of a container according to an embodiment, respectively.

FIG. 3 is a perspective view of a lower protector according to a first embodiment.

FIG. 4 is a cross-sectional view taken along line I-I′ of FIG. 3.

FIG. 5 is a front view of a lower protector on which a display device is seated, the lower protector constituting a container.

FIG. 6 is a perspective view of a lower protector according to a second embodiment.

FIG. 7 is a perspective view of a lower protector according to a third embodiment.

FIG. 8 is a perspective view of a lower protector according to a fourth embodiment.

FIG. 9 is a perspective view of a lower protector according to a fifth embodiment.

FIG. 10 is a perspective view of a lower protector according to a sixth embodiment.

FIG. 11 is a perspective view of a lower protector according to a seventh embodiment.

FIG. 12 is a perspective view of a lower protector according to an eighth embodiment.

FIG. 13 is a perspective view of a lower protector according to a ninth embodiment.

FIG. 14 is a perspective view of a lower protector according to a tenth embodiment.

### MODE FOR THE INVENTION

Hereinafter, embodiments will be described in detail with reference to accompanying drawings.

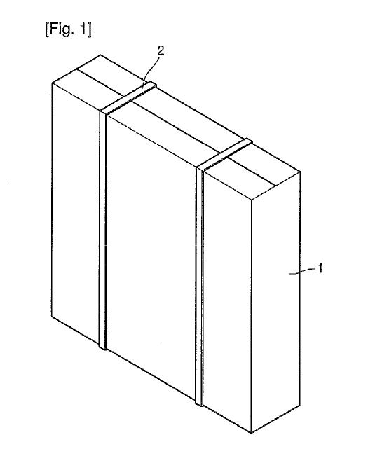

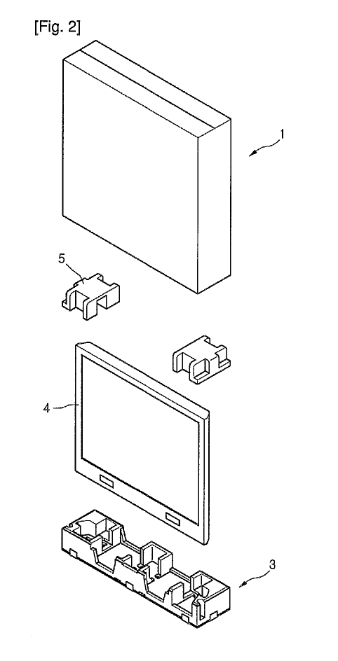

FIGS. 1 and 2 are a perspective view and an exploded perspective view of a container according to an embodiment, respectively.

Referring to FIGS. 1 and 2, a container of the present disclosure is tied by a packing string 2 surrounding an upper protector 1 and a lower protector 3 in a state where a display device (See reference numeral 4 of FIG. 2) is received in the container. The container may be maintained in a tight-packing state due to the packing string.

The container includes upper corner protectors 5, a lower protector 3, and an upper protector 1. The upper corner protectors 5 support both corner portions of an upper portion of the display device 4. The lower protector 3 protects a lower portion of the display device 4. The upper protector 1 covers the display device 4 to protect the display device 4.

The display device 4 is fitted into the lower protector 3 to stably maintain its position. The lower protector 3 supports the display device 4 from below to stably maintain a position of the display device 4. The upper protector 1 is formed of a material such as a corrugated cardboard. The upper protector 1 covers the display device 4 and the lower protector 3 from an upward direction toward a downward direction.

The packing string 2 surrounds the upper protector 1 and the lower protector 3 in a state where the upper protector 1 and the lower protector 3 are stably engaged with each other to complete a packing operation. When the packing operation is completed, delivering and keeping operations may be performed.

According to the present disclosure, post-operations such as maintenance and repair can be performed without entirely separating the container. Hereinafter, a configuration of the lower protector in which the above-described operations can be performed will be described in further detail. In following description, descriptions with respect to a display, an upper protector, and an upper cover protector will be quoted from those described in FIGS. 1 and 2.

### First Embodiment

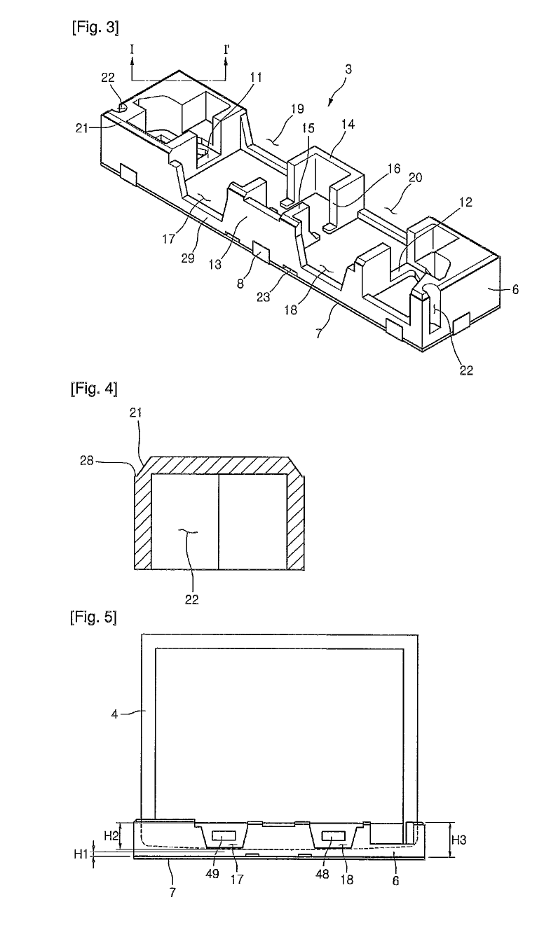

FIG. 3 is a perspective view of a lower protector according to a first embodiment.

Referring to FIG. 3, a lower protector 3 of this embodiment includes a structural member 6 on which a display device 4 is seated and a bottom member 7 disposed on a bottom surface of the structural member 6. The structural member 6 and the bottom member 7 may be attached to each other using an adhesive, or may be integrated using a tape or a method in which the structural member 6 and the bottom member 7 are fitted to each other at a predetermined position. In the drawings, a method in which the structural member 6 and the bottom member 7 are integrated using the tape 8 is described as example.

The bottom member 7 will be described in further detail.

The bottom member 7 may include a corrugated cardboard formed of a material such as a paper and a plastic, a honey pad, and an angle member including a predetermined strength reinforcement structure. The honey pad and the angle member may be used in a case where a self-weight of the display device 4 is heavy.

The bottom member 7 has a plate shape and supports the structural member 6 from below. Since the structural member 6 is not exposed to the outside due to the bottom member 7, it can prevent the structural member 6 from generating scraps by being broken due to a packing string 2. Also, when pushed in a packed state, it can prevent the structural member 6 from generating the scraps by being chafed against a floor. Since the bottom member 7 provides a predetermined strength, the bottom member 7 further reinforces strength of the structural member 6 to achieve a strength reinforcement effect against the self-weight of the display device 4.

If the self-weight of the display device 4 is reached to a significant level, the honey pad or the angle member may be used.

The bottom member 7 may be disposed on not an entire bottom surface but a portion of the structural member 6. For example, the bottom member may be disposed on only a path by which the packing string 2 passes or only a circumference of the structural member 6. In this case, since the bottom member 7 can protect a bottom portion of the structural member 6 formed of a soft material having elasticity, the bottom member 7 may be called a bottom protection member.

The structural member 6 will be described in further detail.

The structural member 6 is formed of styrofoam, and also may be formed of expanded polypropylene (EPP) or expanded polystyrene (EPS). However, the present disclosure is not limited thereto. For example, a paper may be formed in a predetermined shape to fabricate the structural member 6. If a member providing a predetermined shock-absorbing effect is used, a material of the member is not limited.

The structural member 6 includes a left display seat 11 and a right display seat 12 that support the self-weight of the display device 4 at left and right sides.

A lower side portion of the display device 4 is seated on the left and right display seats 11 and 12. Since recesses of the seat 11 and 12 have a shape corresponding to an outer appearance of the display device 4, the display device 4 is stably seated.

The left and right display seats 11 and 12 are connected to each other by a connection member 29. Since the left and right display seats 11 and 12 are integrated by the connection member 29, the lower protector 3 may be easily coupled even if the structural member 6 is correspondingly seated on a top surface of the bottom member 7. That is to say, a shape of a bottom surface of the structural member 6 and a shape of a top surface of the bottom member 7 are provided in shapes attachable to each other. In addition, the left and right display seats 11 and 12 are seated on a precise position of the bottom member 7 by overlapping the structural member 6 with the bottom member 7 in a vertical direction. Thus, the manufacturing process is easy. Since the structural member 6 is injection-molded using one mold and through one injection process, a mutual position between the left and right display seats 11 and 12 may be precisely set, and the display device 4 may be stably supported.

Openings 17, 18, 19, and 20 are defined in the connection member 29. The openings 17, 18, 19, and 20 are components for following objects. Functional part of the display device 4 can be manipulated from the outside through the openings 17, 18, 19, and 20, or a label of the display device 4 can be observed by the naked eye through the openings 17, 18, 19, and 20. The functional parts of the display device 4 serve as an interface unit of a display device 4 and may include connection units for a power source, a broadcasting signal, and a user's manipulation signal. In detail, a portion at which a remote control receiving part of the display device 4 is disposed is exposed to the outside through a front left opening 17 of the openings. A control part, e.g., a power button, is exposed to the outside through a front right opening 18. A power code terminal of the display device 4 is exposed to the outside through the rear left opening 19. Various signal terminals of the display device 4 are exposed to the outside through the rear right opening 20. The label for displaying specification of the display device 4 may be observed to the outside through any one of the openings. The specification of the display device 4 may be correctly known through the label without entirely removing the container.

As described above, the openings 17, 18, 19, and 20 are portions through which a plurality of parts necessary for operating the display device 4 is exposed to the outside through the lower protector 3 in a state where the display device 4 is seated on the lower protector 3. The openings corresponding to the functional parts of the display device 4 may be variable according to the specification of the display device 4. For example, in case where a terminal is provided at a side of the display device 4, an opening may be defined in a side surface of the structural member 6 to smoothly operate the functional parts of the display device 4.

A front middle support 13 and a rear middle support 14 are disposed at an approximately central portion of the connection member 29. A front contact part 15 and a rear contact part 16 are disposed inside the middle supports 13 and 14. The contact parts are in contact with a frame and/or a panel of the display device 4. Thus, in case where the container is overturned in a state where the display device 4 is received, bend of the frame or damage of the panel capable of occurring at the central portion of the display device 4 can be prevented. Such a structure may be further required in case where the display device 4 is large in size.

An air passage 23 is provided on the bottom surface of the structural member 6. The air passage is a component through which air smoothly flows to evaporate moisture in a keeping process after the structural member 6 is manufactured in case where the structural member 6 is formed of a material such as foamed styrofoam. The air passage 23 may be provided in a side surface or a top surface as well as the bottom surface of the structural member 6.

When the structural member 6 is manufactured, in order to prevent occurrence of local deformation, a lightening groove 22 is disposed in a portion at which the structural member 6 is relatively thick. The lightening groove 22 prevents the foamed styrofoam from being deformed when the foamed styrofoam is foamed and then cooled. The lightening groove 22 may be disposed in left and right end portions of the structural member 6.

An insertion guide 21 is disposed on an upper end portion of the structural member 6. The insertion guide 21 guides a lower end portion of the upper protector 1 to smoothly and downwardly move the lower end portion of the upper protector 1 along the upper end portion of the structural member 6 when the upper protector 1 covers the lower protector 3 to protect the lower protector 3.

FIG. 4 is a cross-sectional view taken along line I-I′ of FIG. 3. Referring to FIG. 4, the insertion guide 21 is inclined outwardly toward a downward direction. Thus, the upper protector 1 inserted from an upward direction is stably moved downwardly along the inclined surface of the insertion guide 21 to facilitate a covering process of the upper protector 1. A jaw 28 is disposed at a lower end portion of the insertion guide 21. A portion of a mold corresponding to a position of the insertion guide 21 is chamfered to form the jaw 28. The jaw 28 has a size that does not interfere with the insertion of the upper protector 1. Referring to FIG. 4, the lightening groove 22 is also disposed at a corner of the structural member 6.

An operation of the container according to the first embodiment will be described below.

Customers tend to experimentally test the display device purchased by oneself at a selling spot. Thus, when the packing string 2 is untied, and the upper protector 1 strips off, the display device 4 is exposed to the outside. In this case, the remote control receiving part, the control part, the power terminal, the signal terminal, and the label as well as the outer appearance of the display device 4 are exposed to the outside. As a result, a manager of the selling spot can connect the parts of the display device 4 to each other, and then experimentally operate the display device 4. In this state, the lower protector 3 temporarily serves as a stand of the display device 4.

When the display device 4 is experimentally operated, the user can accurately detect pixel faults, acoustic anomaly, and product defects that may be generated on a display module, thereby to further improve product reliability. This can be precisely understood when it is compared with the case that the display device 4 takes off the lower protector 3 to test the display device 4 because the openings 17, 18, 19, and 20 are not provided in the lower protector 3 of the container as described in this embodiment.

When software upgrade of the display device is required after the packing of the display device is completed, only the upper protector 1 is separated to connect the signal terminals to each other without entirely dismantling the container, thereby easily performing the upgrade operation of the software. Thus, a seller can further easily perform the post-operation.

In addition, the display device 4 may be previously seated on the lower protector 3 to be used as the container to maintain the display device in an upright state. As a result, an operation software recording, a label attachment, an additional assembly, and a product test can be performed in the upright state of the display device. Thereafter, only the upper protector 1 is covered on the lower protector 3 on which the display device 4 is seated to complete the packing operation. Therefore, productivity can be further improved.

Since the container of this embodiment, i.e., the lower protector may be used as the standing device of the display device even if only temporary, usefulness of the container can be further improved.

FIG. 5 is a front view of a lower protector on which a display device is seated, the lower protector constituting a container.

Referring to FIG. 5, the main components for operating the display device are exposed to the outside of the lower protector 3 in this embodiment. For example, the remote control receiving part 49 is exposed to the outside through the front left opening 17 of the lower protector 3. The control part is exposed to the outside through the front right opening 18 of the lower protector 3. The lower protector 3 may be substantially used as the standing device of the display device at selling, producing, and post-management spots. In some cases, the upper protector 1 may strip off, and cables may be connected to the display device to display the display device at the selling spot. In this case, the lower protector 3 may substantially serve as the standing device of the display device.

A configuration of the lower protector required for supporting the self-weight of the display device as well as exposing the functional parts of the display device to the outside such that the container, i.e., the lower protector 3 stably performs functions as the standing device will described below.

In a configuration of the structural member 6, in case where a bottom thickness of the connection member 29 is H1, a height from a lowest end of the display device 4 to a screen—here, the screen may denote the display module—of the display device is H2. The structural member 6 can stably supports the display device 4 even through the self-weight of the display device 4 becomes gradually greater, as the bottom thickness H1 becomes gradually more greater. However, the structural member 6 unnecessarily increases in size, and also material costs increase. As the height H2 from the lowest end of the display device 4 to the screen of the display device becomes gradually more greater, the display device 4 is stably supported to prevent the display device 4 from being overturned or drawn, or from being damaged by an external impact even if the display device 4 falls down. However, in this case, since a total height H3 of the structural member 6 increases, the material costs and the volume increase. Also, as a width W of the structural member 6 becomes gradually greater in front and rear directions, the strength reinforcement effect increases. However, the material costs and total volume increase likewise.

An optimum structure of the structural member under this background is represented by Equation 1 below.

(H1+H2−30)mm<H3<(H1+H2+30)mm Equation 1

That is, the total height H3 of the structural member 6 ranges within plus or minus 30 mm of the sum of the height H2 from the lowest end of the display device 4 to the screen of the display device 4 and the bottom thickness H1 of the connection member.

Also, the bottom thickness H1 of the connection member 29 is represented by Equation 2 below.

(the number of inch unit of display−10)mm<H1<(the number of inch unit of display)mm Equation 2

For example, in case where the display is 32 inch in size, the thickness of the connection member ranges from about 22 mm to about 32 mm. Although the thickness is represented using the inch unit in Equation 2, the thickness may be represented using a millimeter unit converted from the inch unit.

Also, the width W of the structural member 6 in the front and rear directions is represented by Equation 3 below.

((the number of inch unit of display×6)−40)mm<W<((the number of inch unit of display×6)+40)mm Equation 3

For example, in case where the display is 32 inch in size, the width ranges from about 152 mm to about 232 mm. Although it is represented using the inch unit in Equation 3, the thickness may be represented using a millimeter unit converted from the inch unit.

According to this embodiment, the container can perform a proper function itself as well as a function serving as a stand of the display device. Thus, the display device may be further easily treated at the producing, selling, and post-management spots.

### Second Embodiment

A portion that is not specifically described in a second embodiment will be quoted from that of the first embodiment, and the description thereof will be omitted.

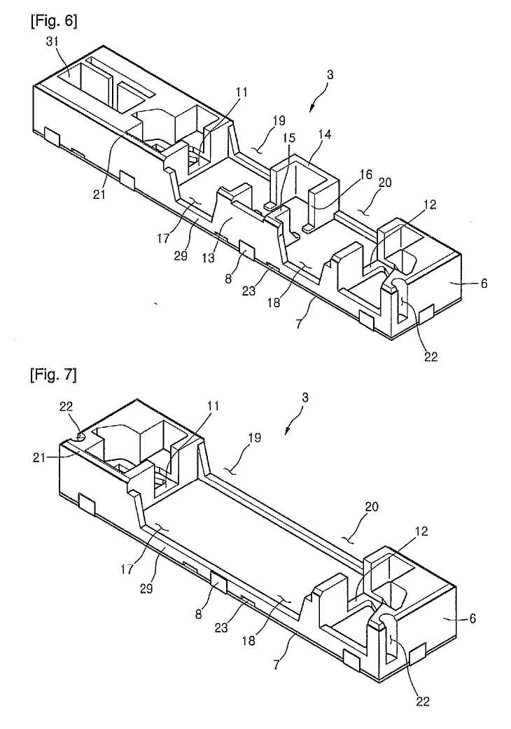

FIG. 6 is a perspective view of a lower protector according to a second embodiment.

Referring to FIG. 6, this embodiment is different from the first embodiment in that a stand receiving part 31 is further disposed at a side of a lower protector 3.

A recess may be defined in the stand receiving part 31 to load a stand that can be permanently used. According to the second embodiment, since a container may include the stand itself to directly assemble the container and the stand by a user, it is a favorite with customers in Europe or America having a high preference with respect to a DIY (do it yourself). In third embodiment, the display device may be further easily treated at producing, selling, and post-management spots.

### Third Embodiment

A portion that is not specifically described in a third embodiment will be quoted from that of the first embodiment, and the description thereof will be omitted.

FIG. 7 is a perspective view of a lower protector according to a third embodiment.

Referring to FIG. 7, a front middle support 13, a rear middle support 14, a front contact part 15, and a rear contact part 16 are not provided in a lower protector 3. The front middle support 13 and the rear middle support 14 are connected to each other, and a rear left opening 19 and a rear right opening 20 are connected to each other. According such a configuration, since the lower protector 3 has a simple shape, manufacture may be easy, and manufacturing costs may be reduced. However, there is a limitation that a central portion of the display device is weakly supported. Thus, this embodiment may be applied to a small display device.

### Fourth Embodiment

A portion that is not specifically described in a fourth embodiment will be quoted from that of the first embodiment, and the description thereof will be omitted.

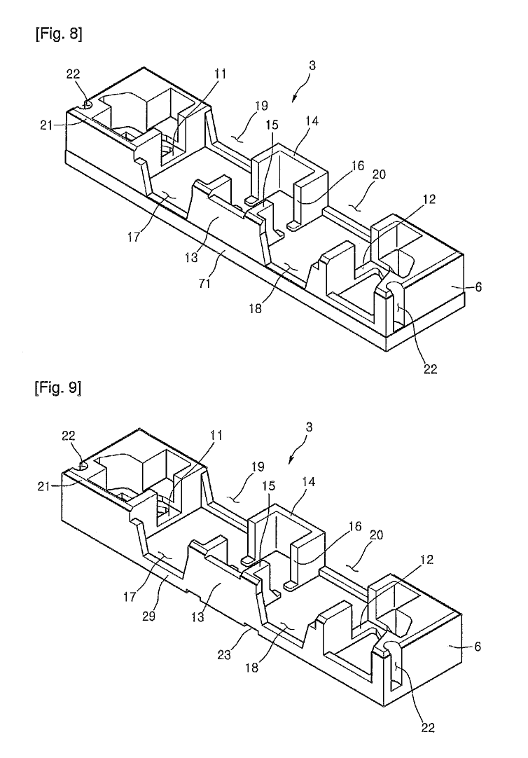

FIG. 8 is a perspective view of a lower protector according to a fourth embodiment.

Referring to FIG. 8, a structural member 6 constituting a lower protector 3 is similar to that of the first embodiment. However, a bottom member disposed on a bottom surface of the structural member 6 is different from that of the first embodiment. A box-shape bottom member 71 is provided as the bottom member. The box-shape bottom member 71 has not a plate shape, but a box-shape having a low height. Thus, the structural member 6 is inserted into an inner space of the box-shape bottom member 71. At this time, a both-side tape is attached to both contact surfaces between the structural member 6 and the box-shape bottom member 71, and then, the structural member 6 is inserted into the box-shape bottom member 71. As a result, the structural member 6 may be positioned in a precise position inside the box-shape bottom member 71. Therefore, manufacture may be further easy.

Here, a height of the box-shape bottom member 71 may not be in excess of that of a connection member 29. Thus, a display device 4 does not interfere with manipulations of functional parts of the display device 4 after the display device 4 is seated on the structural member 6. In addition, manufacturing costs of the box-shape bottom member 71 may be reduced.

According to this embodiment, a coupling operation between the structural member 6 and the box-shape bottom member 71 can be easily performed to improve worker's convenience.

### Fifth Embodiment

A portion that is not specifically described in a fifth embodiment will be quoted from that of the first embodiment, and the description thereof will be omitted.

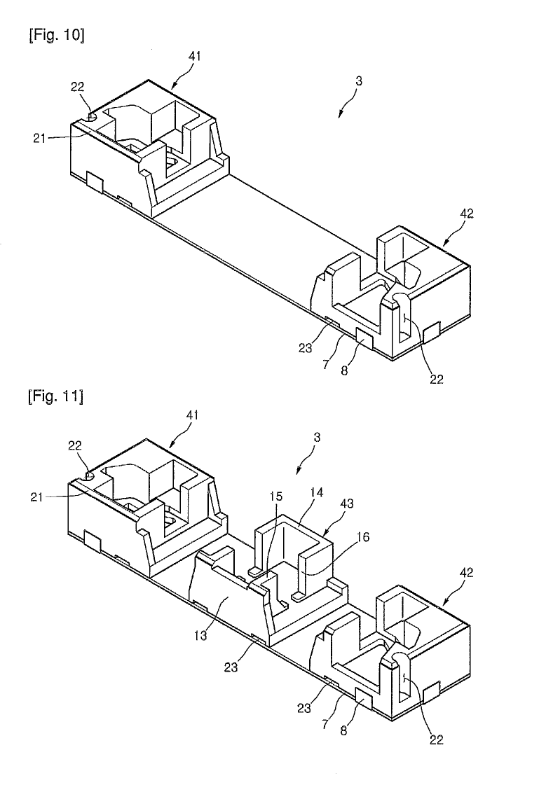

FIG. 9 is a perspective view of a lower protector according to a fifth embodiment.

Referring to FIG. 9, a lower protector 3 is provided as only a structural member 6, and the bottom member 7 disposed on a bottom surface of the structural member 6 in the previously described embodiments is not provided. Thus, this embodiment will be expected to reduce manufacturing costs.

However, since the bottom member 7 is not provided in this embodiment, the structural member 6 may be damaged or generate scraps. Thus, a container and a standing device of a display device according to this embodiment may be used at places at which a travel distance from a producing spot to a selling spot is near, or a state of the selling spot is clean as compared with other places.

In another case, considering fact that the bottom member 7 is not additionally provided, a connection member 29 may be thicker to a certain extent, or a lower end portion of the structural member 6 may be reinforced in order to reinforce strength of the lower protector.

### Sixth Embodiment

A portion that is not specifically described in a sixth embodiment will be quoted from that of the first embodiment, and the description thereof will be omitted.

FIG. 10 is a perspective view of a lower protector according to a sixth embodiment.

Referring to FIG. 10, middle supports 13 and 14 and contact parts 15 and 16 that are provided on a connection member 29 as proposed in the first embodiment are not provided in this embodiment. That is to say, separate parts are provided as left and right display seats 41 and 42, and each is fixed to a top surface of a bottom member 7.

According to such a configuration, although manufacture is difficult somewhat, an environment-friendly product can be manufactured because an amount of a structural member 6 that is treated as a waste matter can be reduced. Also, since components of functional parts of a display device 4 are exposed to the outside in this embodiment, it will be expected to easily perform operations at producing, selling, and post-management spots.

### Seventh Embodiment

A portion that is not specifically described in a seventh embodiment will be quoted from that of the first embodiment, and the description thereof will be omitted.

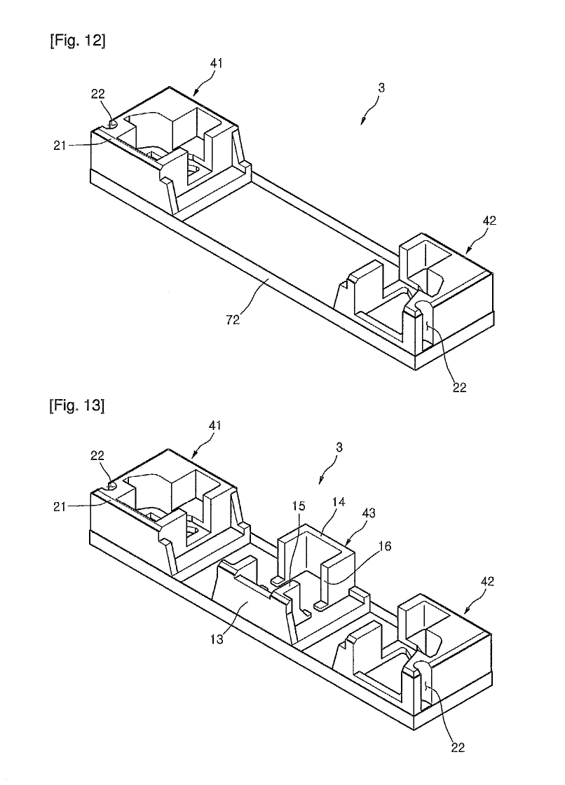

FIG. 11 is a perspective view of a lower protector according to a seventh embodiment.

Referring to FIG. 11, a middle support 43 is further provided on a central portion of a top surface of a bottom member 7. Also, a part separated from left and right display seats 41 and 42 is provided as the middle support 43. Thus, the approximately central portion may be firmly supported by the middle support 43 in a large display device 4. In this case, it can prevent the display device from being damaged or deformed when the display device is overturned.

### Eighth Embodiment

A portion that is not specifically described in an eighth embodiment will be quoted from that of the first embodiment, and the description thereof will be omitted.

FIG. 12 is a perspective view of a lower protector according to an eighth embodiment.

Referring to FIG. 12, a bottom member for supporting a bottom surface of a structural member 6 is provided as a box-shape bottom member 72 having a low height. According to such a configuration, when a lower protector 3 is manufactured, left and right display seats 41 and 42 is insertingly pushed all the way toward end portions of left and right sides of the box-shape bottom member 72 to fix a position thereof. The left and right display seats 41 and 42 may be positioned in a precise position due to a configuration of the box-shape bottom member 72. Therefore, the limitation generated in the sixth and seventh embodiments, i.e., inconvenience of installation of the left and right display seats can be improved.

In this embodiment, since all functional parts of a display device 4 are exposed to the outside of the lower protector 3, the display device 4 may be stably supported in a state where the display device 4 is installed on the lower protector 3. Thus, operations can be conveniently performed at producing, selling, and post-management spots.

### Ninth Embodiment

A portion that is not specifically described in a ninth embodiment will be quoted from that of the first embodiment, and the description thereof will be omitted.

FIG. 13 is a perspective view of a lower protector according to a ninth embodiment.

Referring to FIG. 13, a middle support 43 is further disposed at a central portion of a box-shape bottom member 72. Thus, the approximately central portion of a large display device 4 may be supported by the middle support 43. In this case, it can prevent the display device from being damaged or deformed when the display device is overturned.

### Tenth Embodiment

A portion that is not specifically described in a tenth embodiment will be quoted from that of the first embodiment, and the description thereof will be omitted.

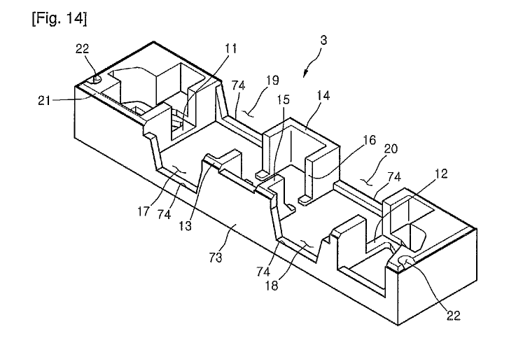

FIG. 14 is a perspective view of a lower protector according to a tenth embodiment.

Referring to FIG. 14, provided is a box-shape bottom member 73 for substantially and entirely protecting an outer surface of a structural member 6. Since the structural member is further protected by the box-shape bottom member 73, the overall strength of a lower protector 3 can further increase.

Also, the box-shape bottom member 73 has openings 17, 18, 19, and 20 having sizes in which the openings 17, 18, 19, and 20 of the structural member 6 are exposed to the outside. According to such a configuration, accessibility with respect to functional parts of a display device and a label can be maintained.

Although various embodiments are proposed, the sprit of the present disclosure is not limited to the proposed embodiments, and a person of ordinary skill in the art would easily propose other embodiments that come within the spirit of the present invention by adding, modifying, and deleting elements, which will be also included in the present invention.

### INDUSTRIAL APPLICABILITY

Although the display is applied to the embodiments, the sprit of the present disclosure is not limited thereto. For example, a good in which verification with respect to a control operation thereof is needed, or various goods in which a position thereof must be stably supported when the control operation is performed may be applied to facilitate their use.

1. A container of a display device, the container comprising:
a lower protector on which the display device is seated; and
an upper protector covering the lower protector,
wherein the lower protector comprises:
a display seat on which a lower portion of the display device is seated; and
openings for exposing a functional part of the display device provided in the lower portion of the display device to the outside of the lower protector in a state where the display device is seated on the display seat.

2. The container according to claim 1, wherein the functional part of the display device comprises at least one of a remote control receiving part, a control part, a power code terminal, and a signal terminal.

3. The container according to claim 1, wherein the lower protector comprises a structural member providing the display seat having at least depressed groove shape.

4. The container according to claim 3, wherein the openings are defined in the structural member.

5. The container according to claim 3, further comprising a bottom member disposed on at least bottom surface of the structural member.

6. The container according to claim 5, wherein the bottom member has a plate shape corresponding to that of the bottom surface of the structural member.

7. The container according to claim 5, wherein the bottom member surrounds at least portion and the bottom surface of the structural member.

8. The container according to claim 7, wherein the openings are defined in the structural member and the bottom member, respectively.

9. The container according to claim 3, wherein the structural member has a width W in front and rear directions, the width W being represented by following equation: ((the number of inch unit of display×6)−40)mm<W<((the number of inch unit of display×6)+40)mm.

10. The container according to claim 3, wherein the structural member comprises:
left and right display seats supporting left and right sides of the display, respectively; and
a connection member connecting the left display seat to the right display seat.

11. The container according to claim 10, wherein the structural member has a height H3 represented by following equation: (H1+H2−30)mm<H3<(H1+H2+30)mm (here, H2 is a height from a lowest end of the display to a screen of the display, and H1 is a bottom thickness of the connection member).

12. The container according to claim 10, wherein the connection member has a bottom thickness H1 represented by following equation: (the number of inch unit of display−10)mm<H1<(the number of inch unit of display)mm.

13. The container according to claim 1, wherein the openings are spaced or connected from/to each other, the openings being defined in at least side of a front surface and a rear surface of the lower protector.

14. The container according to claim 1, wherein a middle support for supporting a front portion and/or a rear portion of the display device is disposed on a central portion of the lower protector.

15. A container of a display device, the container comprising:
a lower protector on which the display device is seated; and
an upper protector covering the lower protector,
wherein the lower protector comprises:
left and right display seats for supporting at least both end portions of the display device;
a connection member connecting the left display seat to the right display seat; and
openings defined between the left and right display seats to expose a functional part of the display device provided in a lower portion of the display device to the outside of the lower protector in a state where the display device is seated on the display seat.

16. The container according to claim 15, wherein the lower protector further comprises a middle support disposed between the left and right display seats to support a front surface and/or a rear surface of the display device.

17. The container according to claim 15, further comprising a bottom protection member for protecting a lower portion of each of the display seats.

18. A container of a display device, the container comprising:
a lower protector on which the display device is seated; and
an upper protector covering the lower protector,
wherein the lower protector comprises:
left and right display seats for supporting at least lower portion of the display device, the left and right display seats being provided as separate parts;
openings defined between the left and right display seats to expose at least one of a remote control receiving part, a control part, a power code terminal, a label part and a signal terminal of the display device to the outside; and
a bottom member for supporting each of the seats.

19. The container according to claim 18, wherein the lower protector further comprises a middle support supported by the bottom member, the middle support being disposed between the left and right display seats to support a front surface and/or a rear surface of the display device.

20. The container according to claim 18, wherein the bottom member has a plate or box shape.
